(19) United States
(12) Patent Application Publication
(10) Pub. No.: US 2024/0418756 A1
(43) Pub. Date: Dec. 19, 2024

(54) Method for determining the conductivity of an electrical conductor between a first system component and a second system component

(71) Applicant: Hilti Aktiengesellschaft, Schaan (LI)

(72) Inventors: Stefan MAYER, Fensterbach (DE); Klaus HAUSER, Schwabmuenchen (DE); Mathias FRENZEL, Unterdiessen (DE); David KOSCHECK, Landsberg (DE)

(21) Appl. No.: 18/704,199

(22) PCT Filed: Nov. 9, 2022
(86) PCT No.: PCT/EP2022/081259

§ 371 Date: Apr. 24, 2024

(30) Foreign Application Priority Data
Nov. 23, 2021 (EP) 21209915.4

(51) Int. Cl. G01R 27/16; G05B 15/02

(52) U.S. Cl. CPC G01R 27/16; G05B 15/02

(57) ABSTRACT

A method for determining the conductivity of an electrical conductor between a first system component and a second system component, the method steps determining a first voltage value and a second voltage value at the first or second system component for a given current intensity value; determining a first differential value between a reference voltage value at the first system component and the first voltage value; determining a second differential value between a reference voltage value at the first system component and the second voltage value; identifying a transition resistance as a quotient from the second differential value and the current intensity value when a difference between the first and second differential values reaches a predetermined threshold value; and adjusting the first and/or second system component from a first operating state into a second operating state and/or emitting at least one signal by means of a display device on the first and/or second system component when the transition resistance reaches a predetermined threshold value.

The present invention relates to a method for determining the conductivity of an electrical conductor between a first system component and a second system component, the first and second system components being parts of a system that are separable from one another, and the first system component being in the form of a rechargeable battery, for example, and the second system component being designed, for example, in the form of a power tool that is connectable to the rechargeable battery or a charging apparatus that is connectable to the rechargeable battery.

Moreover, the present invention also relates to a system having a first and a second system component for carrying out the method according to the invention, the first system component being in the form of a rechargeable battery, for example, and the second system component being designed, for example, in the form of a power tool that is connectable to the rechargeable battery or a charging apparatus that is connectable to the rechargeable battery.

### BACKGROUND

Modern cordless power tools, for example hammer drills, saws, screwdrivers, grinders or the like, can be connected to one or more rechargeable batteries which are used to supply the power tool with electrical energy. Rechargeable batteries are usually connected to charging apparatuses in order to supply electrical energy to the energy storage cells (also called rechargeable battery cells) positioned inside a rechargeable battery.

The prior art includes various apparatuses for sensing and monitoring one or more parameters of a system having two or more system components. The system components can be a rechargeable battery and a power tool connected to the rechargeable battery. Alternatively, the system can consist of a rechargeable battery and a charging apparatus connected to the rechargeable battery.

In order to determine a possible malfunction of one or more system components, the sensed parameters are compared with stored threshold values. If a malfunction is determined on the basis of the parameter comparison, appropriate measures can be taken to prevent greater damage as a result of a total failure of the system.

### SUMMARY OF THE INVENTION

A disadvantage of these already known apparatuses, however, is that a gradual or constantly deteriorating state of a system component is often detected too late by means of the parameter comparison and a malfunction or total failure that often results therefrom is often prevented too late by taking appropriate measures.

It is an object of the present invention to solve the above-described problem and to provide a method and a system with which a gradual or constantly deteriorating state of a system component can be ascertained in a simple manner.

The present invention provides a method for determining the conductivity of an electrical conductor between a first system component and a second system component, the first and second system components being parts of a system that are separable from one another, and the first system component being in the form of a rechargeable battery, for example, and the second system component being designed, for example, in the form of a power tool that is connectable to the rechargeable battery or a charging apparatus that is connectable to the rechargeable battery.

According to the invention, the following method steps are provided:
ascertaining a first voltage value and a second voltage value at the first or second system component at a given current intensity value;
ascertaining a first differential value between a reference voltage value at the first system component and the first voltage value;
ascertaining a second differential value between a reference voltage value at the first system component and the second voltage value;
ascertaining a transfer resistance as a quotient of the second differential value and the current intensity value when a difference between the first and second differential value reaches a predetermined threshold value; and
adjusting the first and/or second system component from a first operating state to a second operating state and/or emitting at least one signal by a display device at the first and/or second system component when the transfer resistance reaches a predetermined threshold value.

By reaching a predetermined threshold value for the transfer resistance or displaying by means of the display device that said predetermined threshold value for the transfer resistance has been reached, a gradual or constantly deteriorating state of a system component can be ascertained in a simple manner. Mechanical stresses or loads on current-carrying conductors, in particular stranded wires, can frequently lead to a deterioration in the conductivity (also known as electrical conductivity or EC value) of the electrical conductor. This is particularly the case when the electrical conductor is stretched and the cross-sectional area is reduced as a result. The electrical conductor can also be referred to as a line or electrical line.

The given current intensity value is a currently ascertained current intensity value at the time of ascertainment of the first and second voltage value.

The reference voltage value is a voltage value as a reference for the first and second ascertained voltage value. The reference voltage value can be a nominal voltage value of the rechargeable battery, for example.

According to an advantageous embodiment of the present invention, it may be possible for the following method step to be involved:
ascertaining a first voltage value and a second voltage value at at least one power terminal, the at least one power terminal being part of the first system component or the second system component.

The power terminal is positioned in an electrical conductor such that the conductivity of the electrical conductor can be ascertained by ascertaining the conductivity at the power terminal. The electrical conductor can also be referred to as a line or stranded wire.

According to a further advantageous embodiment of the present invention, it may be possible for the second voltage value to be ascertained after a predetermined time period from the ascertainment of the first voltage value. A predetermined time period can be between 0.5 and 2 seconds, and in particular 1 second, here. By ascertaining the second voltage value in a time-controlled manner and at relatively short time intervals, even a relatively rapid change in the conductivity can be detected reliably.

Furthermore, the present invention provides a system having a first and a second system component for carrying out the method according to the invention, the first system component being in the form of a rechargeable battery, for example, and the second system component being designed, for example, in the form of a power tool that is connectable to the rechargeable battery or a charging apparatus that is connectable to the rechargeable battery.

According to the invention, provision is made for the first and/or second system component to contain an apparatus for ascertaining a voltage value, an apparatus for ascertaining a current intensity value, a storage apparatus, and a control apparatus.

In this context, the first system component can be designed in the form of a rechargeable battery and the second system component can be designed in the form of a power tool. Alternatively, the second system component is designed in the form of a charging apparatus.

The rechargeable battery is used to supply the power tool with electrical energy when the rechargeable battery and the power tool are connected to one another. Furthermore, the rechargeable battery can be supplied with electrical energy by the charging apparatus when the rechargeable battery and the charging apparatus are connected to one another.

Further advantages will become apparent from the following description of the figures. Various exemplary embodiments of the present invention are illustrated in the figures.

### BRIEF DESCRIPTION OF THE DRAWINGS

The figures, the description and the claims contain numerous features in combination. A person skilled in the art will expediently also consider the features individually and combine them to form useful further combinations.

Identical and similar components are denoted by the same reference signs in the figures, In the drawing:

FIG. 1 shows a system according to a first embodiment having a power tool as a first system component and a rechargeable battery connected to the power tool as a second system component;

FIG. 2 shows a system according to a second embodiment having a charging apparatus as a first system component and the rechargeable battery connected to the charging apparatus as a second system component;

FIG. 3 shows a detailed view of the power terminals of the power tool and the rechargeable battery, and the associated lines;

FIG. 4 shows a detailed view of the power terminals of the charging apparatus and the rechargeable battery, and the associated lines;

FIG. 5 shows a detailed view of a power terminal in a first state;

FIG. 6 shows a further detailed view of the power terminal in a second state; and

FIG. 7 shows an additional detailed view of the power terminal in a third state.

### DETAILED DESCRIPTION

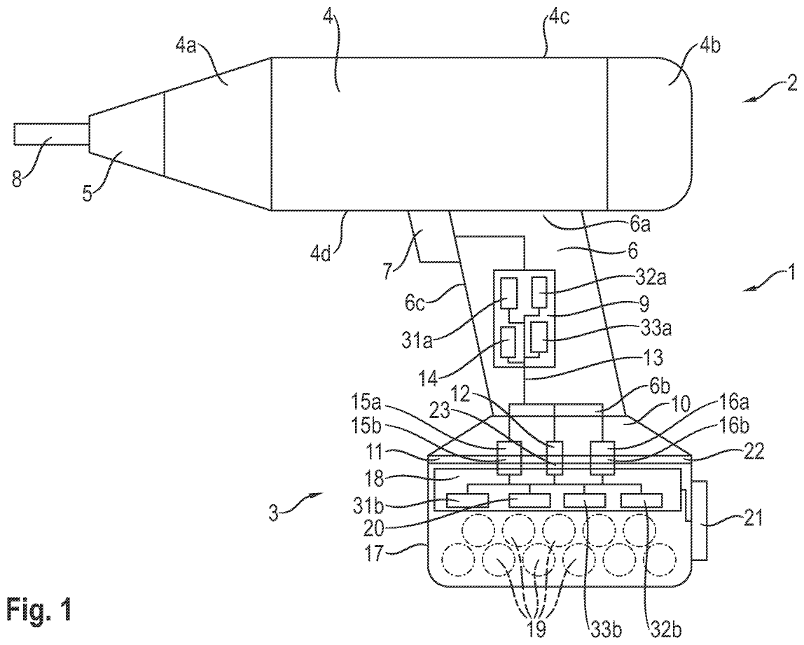

FIG. 1 shows a system 1 according to the invention according to a first exemplary embodiment having a first system component and a second system component.

In this case, according to the first exemplary embodiment, the first system component is in the form of a power tool 2 and the second system component is in the form of a rechargeable battery 3. The power tool 2 illustrated in FIG. 1 is in the form of a cordless screwdriver, for example. The second system component in the form of a rechargeable battery 3 is releasably connected to the first system component in the form of a power tool 2 in FIG. 1.

Alternatively, the power tool 2 can also be in the form of a hammer drill, a drill, a grinder, a saw or the like.

As is likewise clear in FIG. 1, the power tool 2 in the form of a cordless screwdriver contains substantially a tool housing 4, a tool fitting 5 and a handle 6.

The handle 6 in turn contains an upper end 6a and a lower end 6b, and is used by a user to hold and guide the power tool 2. An activation switch 7 is positioned on a front side 6c of the handle 6. A user can use the activation switch 7 to adjust the power tool 2 from a deactivation state into an activation state. In this case, the activation switch 6 contains a potentiometer.

The tool housing 4 in turn contains a front end 4a, a rear end 4b, a top side 4c and an underside 4d.

The tool fitting device 5 is positioned at the front end 4a of the tool housing 4. The tool fitting 5 serves to receive and hold a tool 8. In the present exemplary embodiment, the tool 8 is in the form of a bit (also referred to as a screwdriver bit).

Essentially, a drive, a gear mechanism, a control unit 9, a first apparatus for ascertaining a voltage value 31a, a first apparatus for ascertaining a current intensity value 32a, a first storage unit 33a, and a drive shaft are positioned inside the tool housing 4.

In the present exemplary embodiment, the control unit 9 contains the first apparatus for ascertaining a voltage value 31a, the first apparatus for ascertaining a current intensity value 32a, and the first storage unit 33a.

The apparatus for ascertaining a voltage value 31a serves to ascertain voltages and can also be referred to as a voltmeter.

The apparatus for ascertaining a current intensity value 32a is used to determine the electrical current intensity and can also be referred to as an ammeter.

Alternatively, the first apparatus for ascertaining a voltage value 31a, the first apparatus for ascertaining a current intensity value 32a, or the first storage unit 33a can also be positioned at another suitable point in the power tool 2.

The storage unit 33a serves to store and provide data and information and is connected via a corresponding line S to each of the apparatus for ascertaining a voltage value 31a, the first apparatus for ascertaining a current intensity value 32a, and the first transceiver 14.

The drive, the gear mechanism, and the drive shaft are arranged with respect to one another in the interior of the housing of the power tool, in such a manner that a torque generated by the drive can be transmitted to the drive shaft via the gear mechanism. The drive shaft is in turn connected to the tool fitting 5, with the result that the torque can also be transmitted to the tool fitting 5 and finally to the tool 8 in the form of a bit.

The drive is in the form of a brushless electric motor. Alternatively, however, the drive can also be in the form of an electric motor with carbon brushes.

None of the drive, the gear mechanism and the drive shaft are illustrated in the figures.

The upper end 6a of the handle 6 is secured to the underside 4d of the power tool housing 4.

A base apparatus 10 containing a power tool interface 11 is positioned at the lower end 6b of the handle 6. The power tool interface 11 serves for releasably connecting the rechargeable battery 3 to the power tool 2.

The power tool interface 11 in turn contains a first power terminal 15a, a second power terminal 16a, and a first communication contact 12a. In the present exemplary embodiment, the first power terminal 15a is designed in the form of a positive contact and the second power terminal 16a is designed in the form of a negative contact.

Alternatively, the first power terminal 15a can also contain two or more positive contacts and the second power terminal 16a can also contain two or more negative contacts.

As also described in detail below, the first power terminal 15a designed as a positive contact and the second power terminal 16a designed as a negative contact are used to produce a circuit so that electrical energy can pass from the rechargeable battery 3 to the power tool 2.

The first power terminal 15a is connected to the first apparatus for ascertaining a voltage value 31a via a first line L1 and to the first apparatus for ascertaining a current intensity value 32a via a second line L2. A voltage value and current intensity value can be ascertained at the first power terminal 15a via the first and second line L1, L2. Moreover, the second power terminal 16a is connected to the first apparatus for ascertaining a voltage value 31 via a third line L3 and to the first apparatus for ascertaining a current intensity value 32a via a fourth line L4. A voltage value and current intensity value can be ascertained at the second power terminal 16a via the third and fourth line L3, L4.

The respective line L1, L2, L3, L4 can also be referred to as an electrical line, electrical conductor or stranded wire.

The first communication contact 12 of the power tool 2 is part of a wired transmission device 13 for interchanging data and information between the power tool 2 and another communication partner (for example the rechargeable battery 3).

In the present exemplary embodiment, the control unit 9 of the power tool 2 is positioned inside the handle 6. Alternatively, the control unit 9 may also be positioned at another suitable location in or on the power tool 2. The control unit 9 is used to control and regulate the different functions of the power tool 2.

Furthermore, the control unit 9 contains a first transceiver 14.

The first transceiver 14 is part of the wired transmission device 13 for interchanging data and information between the power tool 2 and another communication partner. For this purpose, the first transceiver 14 is connected to the first communication contact 12 of the power tool 2 by means of a first communication line 34 in such a manner that data and information can be interchanged in the form of signals between the first transceiver 14 and the first communication contact 12 of the power tool 2.

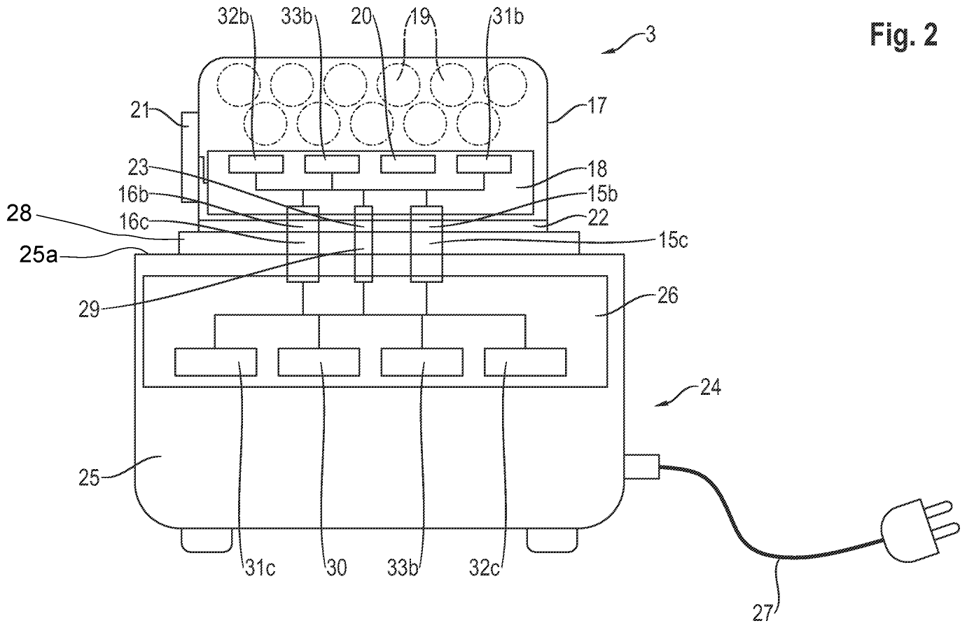

According to the exemplary embodiment shown, the rechargeable battery 3 depicted in FIGS. 1 and 2 substantially contains a battery housing 17, a second apparatus for ascertaining a voltage value 31b, a second apparatus for ascertaining a current intensity value 32b, a second storage unit 33b, a control unit 18, and a number of energy storage cells 19 (also called battery cells).

In the present exemplary embodiment, the control unit 18 of the rechargeable battery 3 contains the second apparatus for ascertaining a voltage value 31b, the second apparatus for ascertaining a current intensity value 32b, and the second storage unit 33b.

The apparatus for ascertaining a voltage value 31b serves to ascertain voltages and can also be referred to as a voltmeter.

The apparatus for ascertaining a current intensity value 32b is used to determine the electrical current intensity and can also be referred to as an ammeter.

Alternatively, the second apparatus for ascertaining a voltage value 31b, the second apparatus for ascertaining a current intensity value 32b, or the second storage unit 33b can also be positioned at another suitable point in the power tool 2.

The second storage unit 33b serves to store and provide data and information and is connected via a corresponding line S to each of the apparatus for ascertaining a voltage value 31b, the first apparatus for ascertaining a current intensity value 32b, and the first transceiver 20.

The energy storage cells 19 are positioned inside the rechargeable battery housing 17 and are used to draw, store and provide electrical energy. Each individual energy storage cell 19 is connected to the control unit 18 via a corresponding line. The line between the individual energy storage cell 19 and the control unit 18 is not illustrated in the figures. In addition, the energy storage cells 19 are connected to a third power terminal 15b designed as a positive contact and to a fourth power terminal 16b of the rechargeable battery 3 designed as a negative contact, with the result that the electrical energy stored in the energy storage cells 19 can be tapped off at the positive contact and the negative contact.

The control unit 18 serves to control and regulate the different functions of the rechargeable battery 3. Furthermore, the control unit 18 contains a second transceiver 20.

The second transceiver 20 of the rechargeable battery 3 is part of the wired transmission device 13 for interchanging data and information of the rechargeable battery 3 with another communication partner (for example the power tool 2 or the charging apparatus 24).

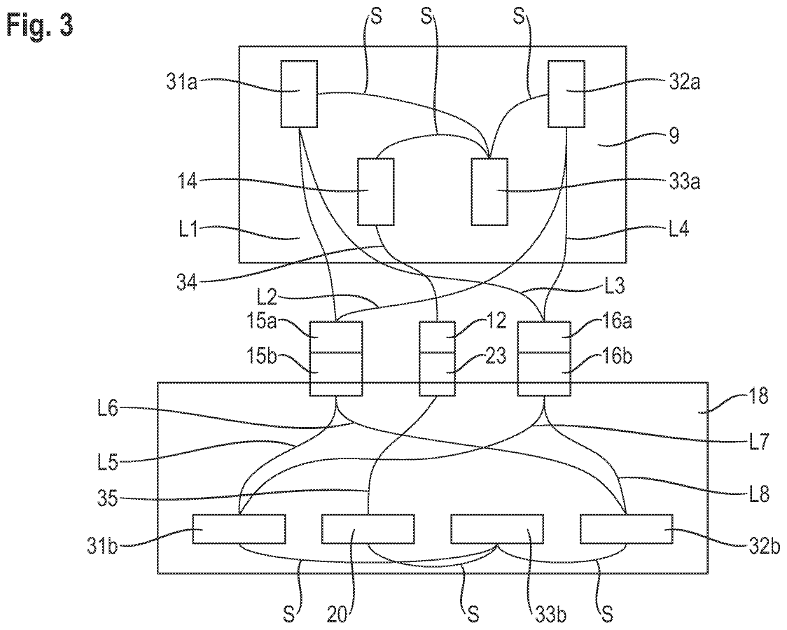

For this purpose, the second transceiver 20 is connected to the first communication contact 23 of the rechargeable battery 3 by means of a second communication line 35 (see, e.g., FIG. 3) in such a manner that data and information can be interchanged in the form of signals between the second transceiver 20 and the second communication contact 23 of the rechargeable battery 3.

On a top side 17a, the rechargeable battery housing 17 contains a rechargeable battery interface 22 which corresponds to the tool interface 11 and is used to releasably connect the rechargeable battery 3 to the power tool 2.

The rechargeable battery interface 22 in turn contains the third power terminal 15b designed as a positive contact, the fourth power terminal 16b designed as a negative contact, and a second communication contact 23.

In order to connect the rechargeable battery 3 to the power tool 2, the rechargeable battery interface 22 is brought into contact with the power tool interface 11 in such a manner that the respective power terminals 15a, 15b, 16a, 16b (i.e., the respective positive contacts and negative contacts) and communication contacts 12, 23 are connected to one another. Making contact with the power terminals 15a, 15b, 16a, 16b makes it possible to close a circuit such that electrical energy can pass from the energy storage cells 19 of the rechargeable battery 3 to the power tool 2 via the respective interfaces 11, 22.

The third power terminal 15b is connected to the second apparatus for ascertaining a voltage value 31b via a fifth line L5 and to the second apparatus for ascertaining a current intensity value 32b via a sixth line L6 (see, e.g., FIG. 3). A voltage value and current intensity value can be ascertained at the third power terminal 15b via the fifth and sixth line L5, L6. Moreover, the fourth power terminal 16b is connected to the second apparatus for ascertaining a voltage value 31b via a seventh line L7 and to the second apparatus for ascertaining a current intensity value 32b via an eighth line L8. A voltage value and current intensity value can be ascertained at the fourth power terminal 16b via the seventh and eighth line L7, L8.

The respective line L5-L8 can also be referred to as an electrical line, electrical conductor or stranded wire.

As a result of the fact that the first communication contact 12 of the power tool 2 and the second communication contact 23 of the rechargeable battery 3 are connected, data and information can be interchanged in the form of signals between the rechargeable battery 3 and the power tool 2.

FIG. 2 shows a system according to the invention according to a second exemplary embodiment having a first system component and a second system component. The first system component is in the form of a charging apparatus 24 and the second system component is in the form of the rechargeable battery 3.

The charging apparatus 24 is used to supply a connected rechargeable battery 3 with electrical energy and substantially contains a charging apparatus housing 25, a control unit 26, a third apparatus for ascertaining a voltage value 31c, a third apparatus for ascertaining a current intensity value 32c, a third storage unit 33c, and a power supply 27.

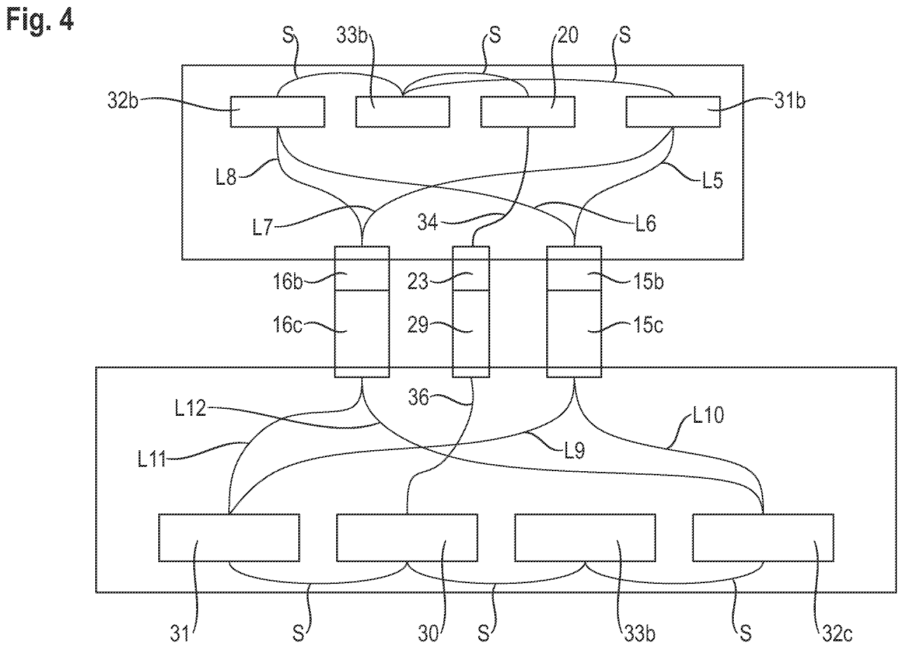

The storage unit 33c serves to store and provide data and information and is connected via a corresponding line S to each of the apparatus for ascertaining a voltage value 31c, the first apparatus for ascertaining a current intensity value 32c, and the first transceiver 30. (See, e.g., FIG. 4).

In the present exemplary embodiment, the control unit 26 contains the third apparatus for ascertaining a voltage value 31c, the third apparatus for ascertaining a current intensity value 32c, and the third storage unit 33c.

The apparatus for ascertaining a voltage value 31c serves to ascertain voltages and can also be referred to as a voltmeter.

The apparatus for ascertaining a current intensity value 32c is used to determine the electrical current intensity and can also be referred to as an ammeter.

Alternatively, the third apparatus for ascertaining a voltage value 31c, the third apparatus for ascertaining a current intensity value 32c, or the third storage unit 33c can also be positioned at another suitable point in the charging apparatus 24.

On a top side 25a, the charging apparatus housing 25 also contains a charging apparatus interface 28 which is used to releasably connect the charging apparatus 24 to the rechargeable battery 3.

The charging apparatus interface 28 in turn contains a fifth power terminal 15c designed as a positive contact, a sixth power terminal 16c designed as a negative contact, and a third communication contact 29. The positive contact and the negative contact are used to produce a circuit so that electrical energy can pass from the charging apparatus 24 to the rechargeable battery 3, in particular to the energy storage cells 19.

The fifth power terminal 15c is connected to the third apparatus for ascertaining a voltage value 31c via a ninth line L9 and to the third apparatus for ascertaining a current intensity value 32c via a tenth line L10 (see e.g., FIG. 4). A voltage value and current intensity value can be ascertained at the fifth power terminal 15c via the ninth and tenth line L10. Moreover, the sixth power terminal 16c is connected to the third apparatus for ascertaining a voltage value 31c via an eleventh line L11 and to the third apparatus for ascertaining a current intensity value 32c via a twelfth line L12. A voltage value and current intensity value can be ascertained at the sixth power terminal 16c via the eleventh and twelfth line L11, L12.

The respective line L9-L12 can also be referred to as an electrical line, electrical conductor or stranded wire.

The third communication contact 29 of the charging apparatus 24 is part of a wired transmission device 13 for interchanging data and information between the charging apparatus 24 and another communication partner (for example the rechargeable battery 3).

The control unit 26 serves to control and regulate the different functions of the charging apparatus 24. Moreover, the control unit 26 contains a third transceiver 30.

The third transceiver 30 is part of a wired transmission device 13 for interchanging data and information between the charging apparatus 24 and another communication partner. For this purpose, the first transceiver 30 is connected to the third communication contact 29 of the charging apparatus 24 by means of a third communication line 36 in such a manner that data and information can be interchanged in the form of signals between the third transceiver 30 and the third communication contact 29 of the charging apparatus 24.

As can be seen in FIG. 2, the energy supply 27 is in the form of a power cable. The charging apparatus 24 can be connected to a power grid (that is to say a socket) by means of the energy supply 27 in the form of the power cable.

Alternatively, the charging apparatus 24 may also be in the form of a mobile energy supply device. Such mobile energy supply devices may also be referred to as a power bank.

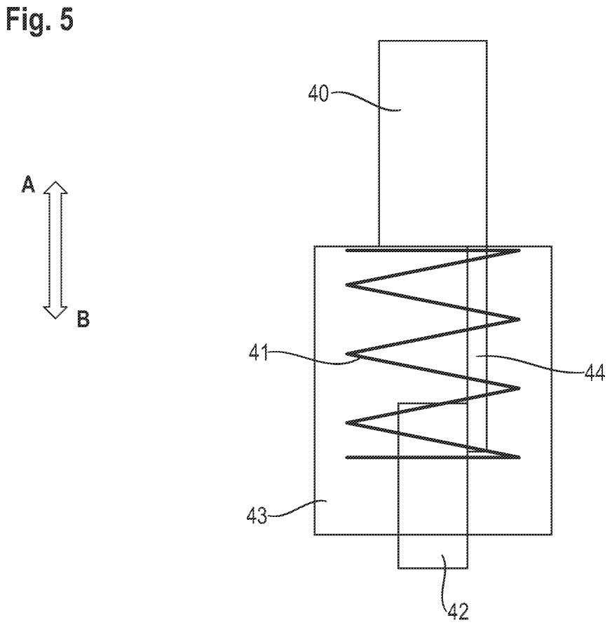

FIGS. 5 to 7 show a power terminal in exemplary fashion. The design of the power terminal shown in FIGS. 5 to 7 corresponds to that of the first to sixth power terminal 15a, 15b, 16a, 16b, 15c, 16c.

Here, the power terminal 15a, 15b, 16a, 16b, 15c, 16c essentially contains a first contact element 40, a spring element 41, a second contact element 42, a contact housing 43, and an electrical connecting line 44.

The first contact element 40 is positioned at an upper end of the contact housing 43. The second contact element 42 is positioned at a lower end of the contact housing 43 so that the second contact element 42 partially protrudes from the contact housing 43. The spring element 41 connects the first and second contact element 40, 42 to one another so that the first and second contact element 40, 42 can be moved relative to one another in direction A or B. The connecting line 44 connects the first and second contact element 40, 42 to one another and is designed in such a way here that there is an electrical connection between the first and second contact element 40, 42. Electrical energy can be transported through the electrical connecting line 44 between the first and second contact elements 40, 42. The electrical connecting line 44 is designed at least long enough for the entire range of spring of the spring element 41 to be able to be implemented in direction A or B.

Here, FIG. 5 shows a first state of the power terminal 15a, 15b, 16a, 16b, 15c, 16c designed in exemplary fashion. The first state is an original, unchanged or undamaged state of the power terminal 15a, 15b, 16a, 16b, 15c, 16c. It is evident that the electrical connecting line 44 between the first and second contact elements 40, 42 has a constant diameter or a constant cross-sectional area throughout.

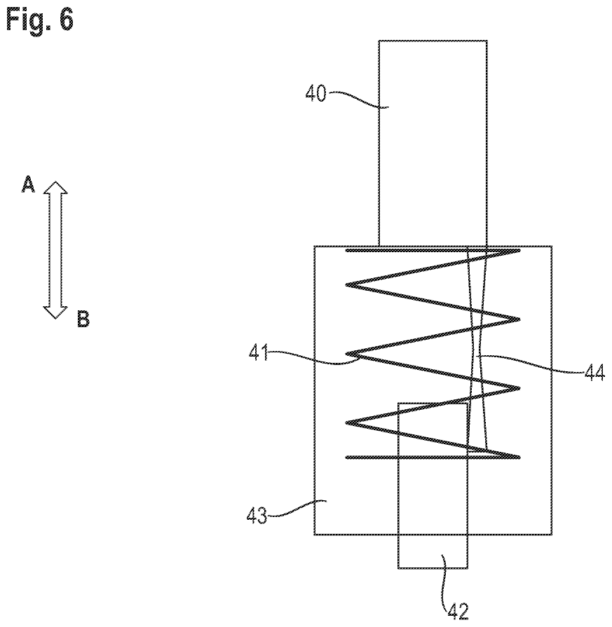

FIG. 6 shows a second state of the power terminal 15a, 15b, 16a, 16b, 15c, 16c designed in exemplary fashion. In contrast to the first state, the second state is a changed or damaged state of the power terminal 15a, 15b, 16a, 16b, 15c, 16c, in which the electrical connecting line 44 between the first and second contact elements 40, 42 has a constricted section with a smaller diameter or a reduced cross-sectional area. The second or damaged state of the power terminal 15a, 15b, 16a, 16b, 15c, 16c is the consequence of an increased mechanical load on account of vibrations or shocks on the power terminal 15a, 15b, 16a, 16b, 15c, 16c.

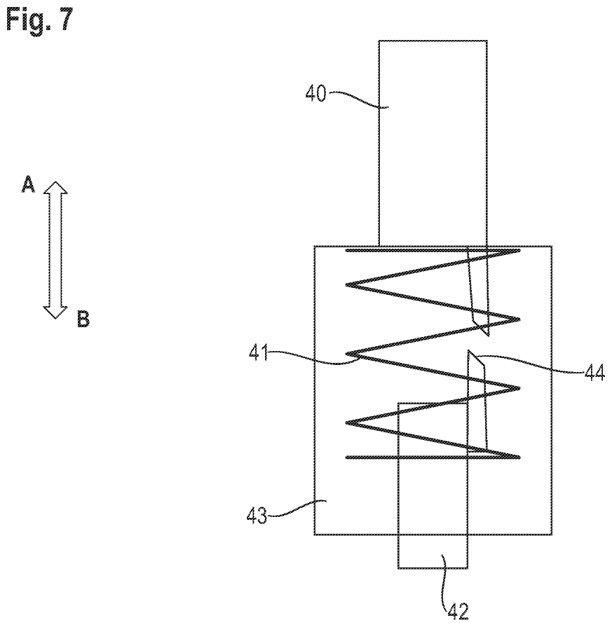

FIG. 7 shows a third state of the power terminal 15a, 15b, 16a, 16b, 15c, 16c designed in exemplary fashion. Likewise in contrast to the first state, the third state is a changed or damaged state of the power terminal 15a, 15b, 16a, 16b, 15c, 16c. In contrast to the second state, the electrical connecting line 44 has been broken in the third state, and so electrical energy can no longer be exchanged through the electrical connecting line 44 and in particular between the first and second contact elements 40, 42.

To ascertain the state of an electrical conductor, the conductivity of the electrical conductor can be determined at a power terminal 15a, 15b, 16a, 16b, 15c, 16c. To carry out the method, a first voltage value and a second voltage value are initially determined at the power tool 2 in the case of an essentially constant current intensity value. The first voltage value can be 21.992 V (V=volts), for example, and the second voltage value can be 21.2 V, for example. The constant current intensity value is 8 A (A=ampere). The voltage values are ascertained by the first apparatus for ascertaining a voltage value of the power tool 2 and while the power tool 2 is in an activated state, that is to say when a rechargeable battery 3 connected to the power tool 2 supplies electrical energy to the power tool 2.

The ascertained second voltage value (=21.2 V) is lower in relation to the first voltage value (=21.992 V) because there was a change in the conductivity of the electrical conductor and in particular at the power terminal 15a, 15b, 16a, 16b, 15c, 16c in the period of time between ascertaining the first voltage value and ascertaining the second voltage value. At the time the first voltage value was ascertained, the electrical connecting line 44 between the first and second contact element of the power terminal 15a, 15b, 16a, 16b, 15c, 16c was still in an original, unchanged or undamaged state, and so there was a relatively high conductivity and a relatively low electrical resistance at the electrical connecting line 44; see FIG. 5. However, at the time the second voltage value was ascertained, the electrical connecting line 44 between the first and second contact element 40, 42 of the power terminal 15a, 15b, 16a, 16b, 15c, 16c was in a changed or damaged state with a reduced cross-sectional area of the electrical connecting line 44, as a result of which there was a poorer conductivity and an increased electrical resistance at the electrical connecting line 44; see FIG. 6.

An extreme example is shown in FIG. 7, in which the electrical connecting line 44 has completely broken through and consequently there is no longer any conductivity.

In a next method step, a first differential value is ascertained between a nominal voltage value at the rechargeable battery 3 and the first voltage value. The nominal voltage value can be 22 V, for example. The first differential value between a nominal voltage value at the rechargeable battery 3 and the first voltage value is therefore 0.008 V in the present exemplary embodiment.

Next, a second differential value is ascertained between the nominal voltage value at the rechargeable battery 3 and the second voltage value. The second differential value between the nominal voltage value (=22 V) at the rechargeable battery 3 and the second voltage value (=21.2 V) is therefore 0.8 V in the present exemplary embodiment.

In a next method step, a transfer resistance is ascertained as a quotient of the second differential value (=0.8 V) and the current intensity value (=8 A) when a difference between the first and second differential value reaches a predetermined threshold value. In the present exemplary embodiment, the predetermined threshold value is 0.1 V. Alternatively, a higher or lower threshold value can also be possible. In the present exemplary embodiment, the difference between the first and second differential value is 0.792 V.

The transfer resistance as the quotient of the second differential value (=0.8 V) and the current intensity value (=8 A) is 0.1Ω in the present exemplary embodiment.

In a further method step, the rechargeable battery 3 is adjusted from the first operating state to a second operating state when the ascertained transfer resistance reaches a predetermined threshold value. In the present exemplary embodiment, the predetermined threshold value for the transfer resistance is 0.05Ω. As a result of the ascertained transfer resistance being 0.1Ω, it is possible to ascertain that a change has occurred in the electrical connecting line 44 and in particular in the power terminal 15a, 15b, 16a, 16b, 15c, 16c, which change has an influence on the electrical resistance or conductivity. As a consequence thereof, the rechargeable battery 3 is switched from an activation mode (=first operating state) to a deactivation mode (=second operating state). In the deactivation state, no electrical energy is conducted from the rechargeable battery 3 to the power tool 2.

As an alternative or in addition, the change in the operating state is displayed on a display device 21 of the rechargeable battery 3. A signal is transmitted from the control unit 18 to the display device 21 in order to display corresponding information on the display device 21 of the rechargeable battery 3.

It is to be understood that the above-described method for determining the conductivity of an electrical conductor is also applicable if the first system component is configured by the rechargeable battery 3 and the second system component by the charging apparatus 24.

### LIST OF REFERENCE SIGNS

1 System
2 Power tool
3 Rechargeable battery
4 Power tool housing
4a Front end of the power tool housing
4b Rear end of power tool housing
4c Top side of the power tool housing
4d Underside of the power tool housing
5 Tool fitting
6 Handle
6a First end of the handle
6b Second end of the handle
6c Front side 6c of the handle
7 Activation switch
8 Tool fitting
9 Control unit of the power tool
10 Base apparatus
11 Power tool interface
12 First communication contact of the power tool
13 Wired transmission device
14 First transceiver of the power tool
15a First power terminal of the power tool
16a Second power terminal of the power tool
15b Third power terminal of the rechargeable battery
16b Fourth power terminal of the rechargeable battery
15c Fifth power terminal of the charging apparatus
16c Sixth power terminal of the charging apparatus
17 Rechargeable battery housing
18 Control unit of the rechargeable battery
19 Energy storage cell
Second transceiver of the rechargeable battery
21 Display device
22 Rechargeable battery interface
23 Second communication contact of the rechargeable battery
24 Charging apparatus
25 Charging apparatus housing
26 Control unit of the charging apparatus
27 Energy supply of the charging apparatus
28 Charging apparatus interface
29 Third communication contact of the charging apparatus
Third transceiver of the charging apparatus
31a First apparatus for ascertaining a voltage value of the power tool
32a First apparatus for ascertaining a current intensity value of the power tool
33a First storage unit of the power tool
31b Second apparatus for ascertaining a voltage value of the rechargeable battery
32b Second apparatus for ascertaining a current intensity value of the rechargeable battery
33b Second storage unit of the rechargeable battery
31c Third apparatus for ascertaining a voltage value of the charging apparatus
32c Third apparatus for ascertaining a current intensity value of the charging apparatus
33c Third storage unit of the charging apparatus
34 First communication line
35 Second communication line
36 Third communication line
40 First contact element
41 Spring element
42 Second contact element
43 Contact housing
44 Connecting line
L1 First line
L2 Second line
L3 Third line
L4 Fourth line
L5 Fifth line
L6 Sixth line
L7 Seventh line
L8 Eighth line
L9 Ninth line
L10 Tenth line
L11 Eleventh line
L12 Twelfth line
S Line to and from the storage unit

What is claimed is:

1-4. (canceled)

5. A method for determining the conductivity of an electrical conductor between a first system component and a second system component, the first and second system components being parts separable from one another, and the first system component being in the form of a rechargeable battery and the second system component being designed in the form of a power tool connectable to the rechargeable battery or a charging apparatus connectable to the rechargeable battery, the method comprising the steps of:
ascertaining a first voltage value and a second voltage value at the first or second system component at a given current intensity value;
ascertaining a first differential value between a reference voltage value at the first system component and the first voltage value;
ascertaining a second differential value between a reference voltage value at the first system component and the second voltage value;
ascertaining a transfer resistance as a quotient of the second differential value and the current intensity value when a difference between the first and second differential value reaches a predetermined threshold value; and
adjusting the first or second system component from a first operating state to a second operating state or emitting at least one signal by a display device at the first or second system component when the transfer resistance reaches a predetermined threshold value.

6. The method as recited in claim 5 further comprising ascertaining a first voltage value and a second voltage value at at least one power terminal, the at least one power terminal being part of the first system component or the second system component.

7. The method as recited in claim 5 wherein the second voltage value is ascertained after a predetermined time period from the ascertainment of the first voltage value.

8. A system comprising: a first and a second system component for carrying out the method as recited in claim 5, first system component being in the form of a rechargeable battery and the second system component being designed in the form of a power tool connectable to the rechargeable battery or a charging apparatus is connectable to the rechargeable battery, the first or second system component containing an apparatus for ascertaining a voltage value, an apparatus for ascertaining a current intensity value, a storage apparatus, and a control apparatus.
